(19) United States
(12) Patent Application Publication
(10) Pub. No.: US 2025/0359200 A1
(43) Pub. Date: Nov. 20, 2025

(54) SEMICONDUCTOR STRUCTURE AND FABRICATING METHOD THEREOF

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/893,812

(22) Filed: Sep. 23, 2024

(30) Foreign Application Priority Data
May 14, 2024 (CN) 202410598791.6

(51) Int. Cl. H01L 29/47; H01L 21/285; H01L 29/20; H01L 29/66; H01L 29/778

(52) U.S. Cl. CPC H10D 62/105; H10D 30/015; H10D 30/475; H10D 62/8503

(57) ABSTRACT

Disclosed are a semiconductor structure and a fabricating method thereof. The semiconductor structure includes a substrate, a channel layer and a barrier layer stacked sequentially, where the channel layer and the barrier layer include a gate region, a source region located at a side of the gate region and a drain region located at another side of the gate region; a first P-type semiconductor layer located in the gate region and at a side, away from the substrate, of the barrier layer, and the first P-type semiconductor layer is configured to implement an enhanced device; and a semiconductor film layer, where the semiconductor film layer covers a sidewall of the first P-type semiconductor layer and an upper surface, away from the substrate, of the first P-type semiconductor layer.

### CROSS-REFERENCE TO RELATED APPLICATIONS

The present disclosure claims priority to Chinese Patent Application No. 202410598791.6, filed on May 14, 2024, all contents of which are incorporated herein in its entirety by reference.

### TECHNICAL FIELD

The present disclosure relates to the field of semiconductor technologies, in particular, to a semiconductor structure and a fabricating method thereof.

### BACKGROUND

Compared with a first-generation semiconductor material and a second-generation semiconductor material, a third-generation semiconductor material, especially a GaN-based material (gallium nitride) has advantages of wide band gap, high breakdown field strength, high electron mobility, strong radiation resistance and the like. The GaN-based High Electron Mobility Transistor (HEMT) device has great development potential in high-frequency and high-power fields such as wireless communication base stations, radars, automobile electronics and the like.

In general, the GaN-based HEMT device is a depletion mode field effect transistor, for example, a negative turn-on voltage needs to be used in a radio frequency microwave application, which makes a circuit structure become complex and the anti-misoperation protection function of the circuit is also affected, and thereby a safety of the circuit is reduced, and therefore, it is necessary to carry out a research on an enhancement mode GaN-based HEMT device. The P-type gate is adopted in a conventional GaN-based HEMT device to achieve enhancement mode, but there are still many problems such as current collapse and relatively large gate leakage current.

### SUMMARY

In view of this, embodiments of the present disclosure provide a semiconductor structure and a fabricating method thereof to solve the technical problem of current collapse in the prior art.

According to an aspect of the present disclosure, the present disclosure provides a semiconductor structure, the semiconductor structure includes: a substrate, a channel layer and a barrier layer stacked sequentially, where the channel layer and the barrier layer include a gate region, a source region located at a side of the gate region and a drain region located at another side of the gate region; a first P-type semiconductor layer located in the gate region and at a side, away from the substrate, of the barrier layer; and a semiconductor film layer, where the semiconductor film layer covers a sidewall of the first P-type semiconductor layer and an upper surface, away from the substrate, of the first P-type semiconductor layer.

In an embodiment of the present disclosure, the semiconductor film layer covers a region between the source region and the gate region and a region between the drain region and the gate region.

In an embodiment of the present disclosure, a band gap of the semiconductor film layer is greater than a band gap of the first P-type semiconductor layer.

In an embodiment of the present disclosure, the semiconductor film layer includes an Al element, and a content of the Al element in the semiconductor film layer is greater than or equal to 35%.

In an embodiment of the present disclosure, a material of the semiconductor film layer is AlGaN or AlN.

In an embodiment of the present disclosure, the semiconductor film layer includes an N-type doping element.

In an embodiment of the present disclosure, a concentration of an N-type doping element in the semiconductor film layer between the source region and the gate region is greater than a concentration of an N-type doping element in the semiconductor film layer between the drain region and the gate region.

In an embodiment of the present disclosure, in a direction perpendicular to a plane where the substrate is located, a thickness of the semiconductor film layer is 2 nm-10 nm.

In an embodiment of the present disclosure, a thickness of the semiconductor film layer is 3 nm-5 nm.

In an embodiment of the present disclosure, the semiconductor structure further includes: a second P-type semiconductor layer located at a side, away from the substrate, of the barrier layer, and the second P-type semiconductor layer being located between the gate region and the drain region.

In an embodiment of the present disclosure, the semiconductor film layer covers a sidewall of the second P-type semiconductor layer and an upper surface, away from the substrate, of the second P-type semiconductor layer.

In an embodiment of the present disclosure, in a direction perpendicular to a plane where the substrate is located, a thickness of the second P-type semiconductor layer is less than a thickness of the first P-type semiconductor layer.

In an embodiment of the present disclosure, a concentration of a P-type doping in the second P-type semiconductor layer is less than a concentration of a P-type doping in the first P-type semiconductor layer.

In an embodiment of the present disclosure, the source region and the drain region each include an N-type doped region, and the N-type doped region extends into the channel layer.

In an embodiment of the present disclosure, the semiconductor structure further includes: a gate located in the gate region and located at a side, away from the substrate, of the semiconductor film layer; a source located in the source region and located at a side, away from the substrate, of the channel layer; and a drain located in the drain region and located at the side, away from the substrate, of the channel layer.

In an embodiment of the present disclosure, in a direction from the gate region to the drain region, a thickness of a portion of the first P-type semiconductor layer gradually decreases between the gate region and the drain region.

According to another aspect of the present disclosure, an embodiment of the present disclosure provides a fabricating method of a semiconductor structure. The fabricating method of the semiconductor structure includes: sequentially epitaxially fabricating a channel layer and a barrier layer on a substrate, where the channel layer and the barrier layer include a gate region, a source region located at a side of the gate region and a drain region located at another side of the gate region; epitaxially fabricating a first P-type semiconductor layer in the gate region at a side, away from the substrate, of the barrier layer; and epitaxially fabricating a semiconductor film layer on the first P-type semiconductor layer, where the semiconductor film layer covers a sidewall of the first P-type semiconductor layer and an upper surface, away from the substrate, of the first P-type semiconductor layer.

In an embodiment of the present disclosure, the epitaxially fabricating a semiconductor film layer on the first P-type semiconductor layer includes: epitaxially fabricating the semiconductor film layer on a full-surface at a side, away from the substrate, of the first P-type semiconductor layer and at a side, away from the substrate, of the barrier layer, so that the semiconductor film layer covers a region between the source region and the gate region and a region between the drain region and the gate region.

In an embodiment of the present disclosure, the semiconductor film layer is conformally fabricated at a side, away from the substrate, of the first P-type semiconductor layer and the barrier layer.

In an embodiment of the present disclosure, after the semiconductor film layer is fabricated epitaxially, the fabricating method further includes: etching the source region and the drain region to form grooves, respectively, where the grooves extends into the channel layer; and fabricating an N-type doped region by secondary epitaxy in the grooves.

### BRIEF DESCRIPTION OF THE DRAWINGS

FIG. 1 is a schematic structural diagram of a semiconductor structure according to an embodiment of the present disclosure.

FIG. 2 is a schematic structural diagram of another semiconductor structure according to an embodiment of the present disclosure.

FIG. 3 is a schematic structural diagram of another semiconductor structure according to an embodiment of the present disclosure.

FIG. 4 is a schematic structural diagram of another semiconductor structure according to an embodiment of the present disclosure.

FIG. 5 is a schematic structural diagram of another semiconductor structure according to an embodiment of the present disclosure.

FIG. 6 is a schematic structural diagram of another semiconductor structure according to an embodiment of the present disclosure.

FIG. 7 to FIG. 10 are schematic structural diagrams of intermediate structures for fabricating a semiconductor structure according to an embodiment of the present disclosure.

FIG. 11 and FIG. 12 are schematic structural diagrams of intermediate structures for fabricating another semiconductor structure according to an embodiment of the present disclosure.

FIG. 13 is a schematic structural diagram of an intermediate structure for fabricating another semiconductor structure according to an embodiment of the present disclosure.

FIG. 14 is a schematic flowchart of a fabricating method of a semiconductor structure according to an embodiment of the present disclosure.

### DETAILED DESCRIPTION OF THE EMBODIMENTS

Technical solutions in the embodiments of the present disclosure will be clearly described below with reference to the accompanying drawings in the embodiments of the present disclosure. Apparently, the described embodiments are a part of the embodiments of the present disclosure, rather than all the embodiments.

In a conventional GaN-based HEMT device with a P-type gate, a gate insulating layer is formed by a plasma chemical vapor phase, or the gate is formed by an electrode process, these ex-situ formation processes result in defects or interface states at the interface between the P-type gate and the gate insulating layer or the gate. Electrons may easily get trapped in these defects or interface states, resulting in current collapse and reducing reliability of the device.

In order to solve the above problems, the present disclosure provides a semiconductor structure, the semiconductor structure includes: a substrate, a channel layer and a barrier layer stacked sequentially, where the channel layer and the barrier layer include a gate region, a source region located at a side of the gate region and a drain region located at another side of the gate region; a first P-type semiconductor layer located in the gate region and at a side, away from the substrate, of the barrier layer; and a semiconductor film layer, where the semiconductor film layer covers a sidewall of the first P-type semiconductor layer and an upper surface, away from the substrate, of the first P-type semiconductor layer.

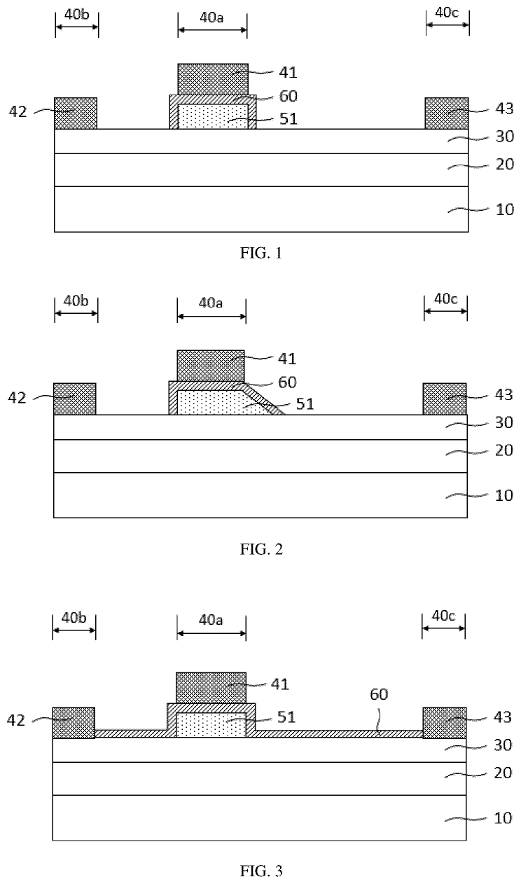

The following further illustrates a semiconductor structure and a fabricating method thereof mentioned in the present disclosure with reference to FIG. 1 to FIG. 13.

FIG. 1 is a schematic structural diagram of a semiconductor structure according to an embodiment of the present disclosure. As shown in FIG. 1, the semiconductor structure includes: a substrate 10, a channel layer 20 and a barrier layer 30 that are stacked sequentially, where the channel layer 20 and the barrier layer 30 include a gate region 40a, a source region 40b located at a side of the gate region 40a and a drain region 40c located at another side of the gate region 40a; a first P-type semiconductor layer 51 located in the gate region 40a and at a side, away from the substrate 10, of the barrier layer 30; and a semiconductor film layer 60, where the semiconductor film layer 60 covers a sidewall of the first P-type semiconductor layer 51 and an upper surface, away from the substrate 10, of the first P-type semiconductor layer 51.

Specifically, as shown in FIG. 1, a heterojunction is composed of the channel layer 20 and the barrier layer 30, and a channel of a two-dimensional electron gas (2DEG) is formed on a surface, close to the barrier layer 30, of the channel layer 20. When no voltage is applied to a semiconductor device, the 2DEG in the channel may be depleted by the first P-type semiconductor layer 51, so as to implement an enhancement mode device. The semiconductor film layer 60 covers a sidewall of the first P-type semiconductor layer 51 and an upper surface, away from the substrate 10, of the first P-type semiconductor layer 51, and the semiconductor film layer 60 is formed in-situ process to completely cover the surface of the of the first P-type semiconductor layer 51. This reduces the defects and interface states introduced on the top surface and the sidewall of the P-type semiconductor during the etching process, reduces the capture of electrons in the defects or interface states, and improves the current collapse, thereby improving reliability of the device.

Optionally, FIG. 2 is a schematic structural diagram of another semiconductor structure according to an embodiment of the present disclosure. As shown in FIG. 2, in a direction from the gate region 40a to the drain region 40c, a thickness of a portion of the first P-type semiconductor layer 51 gradually decreases between the gate region 40a and the drain region 40c, that is, a slope is formed at a side, close to the drain region 40c, of the first P-type semiconductor layer 51. Since the gate region 40a is prone to breakdown at a side close to the drain region 40c, the density of the 2DEG under the channel may be reduced by the first P-type semiconductor layer 51 at the slope, and the electric field strength at a side, close to the drain region 40c, of the gate region 40a is reduced, thereby improving the breakdown voltage of the device. In this case, the semiconductor film layer 60 covers the vertical sidewall of the first P-type semiconductor layer 51, the slope of the first P-type semiconductor layer 51, and the upper surface, away from the substrate 10, of the first P-type semiconductor layer 51. This reduces the defects and interface states introduced on the top surface, the slope, and the sidewall of the P-type semiconductor during the etching process, reduces the capture of the electrons in the defects or interface states, and improves the current collapse, thereby improving the reliability of the device.

In an embodiment, as shown in FIG. 1, the semiconductor structure further includes: a gate 41 located in the gate region 40a and located at a side, away from the substrate 10, of the semiconductor film layer 60; a source 42 located in the source region 40b and located at a side, away from the substrate 10, of the channel layer 20; and a drain 43 located in the drain region 40c and located at a side, away from the substrate 10, of the channel layer 20. Specifically, as shown in FIG. 1, the source 42 and the drain 43 are both located above the barrier layer 30, the source 42 is in ohmic contact with the barrier layer 30, and the drain 43 is also in ohmic contact with the barrier layer 30. Optionally, the source 42 and the drain 43 may penetrate through the barrier layer 30 to form ohmic contacts with the channel layer 20 (not shown).

It should be noted that, as shown in FIG. 2, a portion of the first P-type semiconductor layer with gradually decreased thickness is located between the gate 41 and the drain 43, and the portion of the first P-type semiconductor layer is connected to the remaining portion of the first P-type semiconductor layer under the gate 41.

Optionally, the semiconductor structure further includes a nucleation layer and a buffer layer (not shown in FIG. 1) that are located between the substrate 10 and the channel layer 20, the nucleation layer provides a nucleation site for the subsequent epitaxial growth of the channel layer 20, and the buffer layer is configured to relieve lattice mismatch between the substrate 10 and the channel layer 20, so as to improve the crystal quality of the subsequent epitaxial structure.

In an embodiment, FIG. 3 is a schematic structural diagram of another semiconductor structure according to an embodiment of the present disclosure. As shown in FIG. 3, the semiconductor film layer 60 covers a region between the source region 40b and the gate region 40a and a region between the drain region 40c and the gate region 40a. Specifically, the semiconductor film layer 60 is epitaxially fabricated at a side, away from the substrate 10, of the barrier layer 30 and the first P-type semiconductor layer 51. During later processing, the semiconductor film layer 60 is only etched in the source region 40b and the drain region 40c, reserving positions for forming the source 42 and the drain 43. The semiconductor film layer 60 between the source region 40b and the gate region 40a and the semiconductor film layer 60 between the drain region 40c and the gate region 40a are preserved, so as to avoid the power characteristic of the device from going bad caused by over-etching the barrier layer 30.

In an embodiment, a band gap of the semiconductor film layer 60 is greater than a band gap of the first P-type semiconductor layer 51. Specifically, the surface of the first P-type semiconductor layer 51 is covered by the semiconductor film layer 60 with a relatively large band gap, and a relatively high barrier height may increase the gate operating voltage; and then when the device is in on-state, the semiconductor film layer 60 covering the top surface improves the gate breakdown voltage of the semiconductor device, and when the device is in off-state, the effect of the peak electric field at the sidewall of the first P-type semiconductor layer 51 is reduced. In this way, the working voltage of the device in the on-state is improved, the withstand voltage of the device in the off-state is improved, and reliability of the device is improved.

Optionally, the semiconductor film layer 60 includes an Al element, and a content of the Al element in the semiconductor film layer 60 is greater than or equal to 35%. Specifically, a material of the semiconductor film layer 60 is AlGaN, and the content of the Al element is greater than or equal to 35%, a material of the first P-type semiconductor layer 51 is GaN, and the band gap of the semiconductor film layer 60 is greater than the band gap of the first P-type semiconductor layer 51. Alternatively, the content of the Al element in the semiconductor film layer 60 is 1, the material of the semiconductor film layer 60 is AlN, and the band gap of the AlN is greater than the band gap of the AlGaN, so the breakdown voltage of the device is better improved, and thereby improving the power characteristic of the device. It should be noted that the content of the Al element refers to the proportion of the Al element to the metal ions in the semiconductor film layer, for example when the content of the Al element is 35%, the material of the semiconductor film layer 60 is Al_{0.35}Ga_{0.65}N.

In an embodiment, the semiconductor film layer 60 includes an N-type doping element. Specifically, the semiconductor film layer 60 covers the first P-type semiconductor layer 51. When the gate is forward biased, the PN junction formed by the N-type doping semiconductor film layer 60 and the P-type doping first P-type semiconductor layer 51 is reverse-biased, and this partial space charge region may undertake a part of gate voltage, thereby playing a role in buffering, improving the breakdown voltage of the device, and improving the reliability of the device.

Optionally, a concentration of a P-type doping, close to a portion of the semiconductor film layer 60, of the first P-type semiconductor layer 51 is less than a concentration of a P-type doping, away from a portion of the semiconductor film layer 60, of the first P-type semiconductor layer 51, the concentration of the P-type doping in the first P-type semiconductor layer 51 is different, and a High-Low junction (H-L junction) with different concentrations is formed at the junction. When the gate is forward biased, the H-L junction is reverse-biased, which also plays a role in buffering, thereby improving the breakdown voltage of the device, and improving the reliability of the device.

Optionally, the semiconductor film layer 60 is not intentionally doped.

In an embodiment, the semiconductor film layer 60 covers the region between the source region 42 and the gate region 41, and covers the region between the drain region 43 and the gate region 41, and a concentration of an N-type doping element in the semiconductor film layer 60 between the source region 42 and the gate region 41 is greater than a concentration of an N-type doping element in the semiconductor film layer 60 between the drain region 43 and the gate region 41. Specifically, the concentration of the N-type doping element in the semiconductor film layer 60 between the source region 42 and the gate region 41 is increased, and the concentration of the electron under the channel is increased. Conversely, since the electric field strength at the side, close to the drain, of the gate is relatively great, breakdown is easy to occur, the N-type doping element concentration of the semiconductor film layer 60 between the drain region 43 and the gate region 41 is reduced, the electric field strength at a side, close to the drain, of the gate is appropriately reduced, and the probability of breakdown is reduced.

In an embodiment, in a direction perpendicular to a plane where the substrate 10 is located, a thickness of the semiconductor film layer 60 is 2 nm-10 nm. Optionally, the thickness of the semiconductor film layer 60 is 3 nm-5 nm, and the thinner semiconductor film layer 60 may reduce defects or interface states and avoid affecting the gate control capability of the gate.

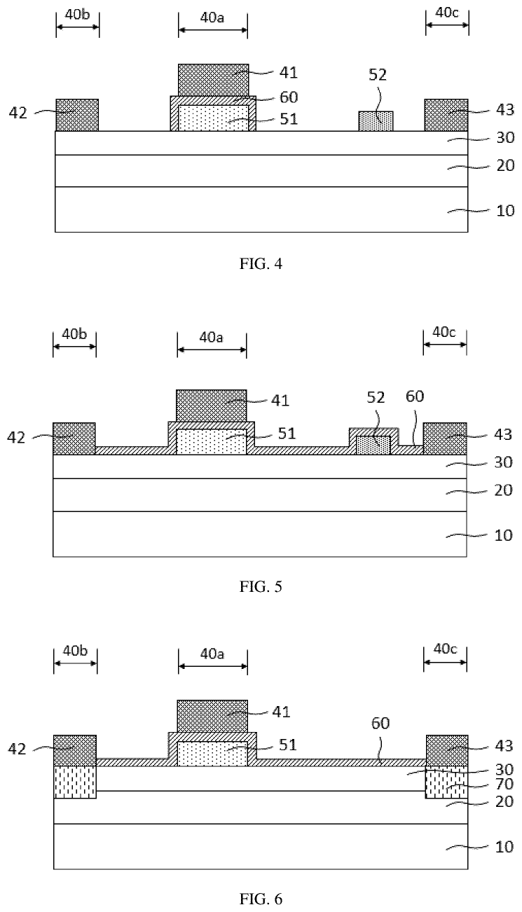

In an embodiment, FIG. 4 is a schematic structural diagram of another semiconductor structure according to an embodiment of the present disclosure. As shown in FIG. 4, the semiconductor structure further includes: a second P-type semiconductor layer 52 located at a side, away from the substrate 10, of the barrier layer 30, and the second P-type semiconductor layer 52 is located between the gate region 40a and the drain region 40c. Specifically, the second P-type semiconductor layer 52 provides a gentle electric field distribution for a side of the drain 43, which may reduce the current collapse.

Optionally, FIG. 5 is a schematic structural diagram of another semiconductor structure according to an embodiment of the present disclosure. As shown in FIG. 5, the semiconductor film layer 60 covers a sidewall of the second P-type semiconductor layer 52 and an upper surface, away from the substrate 10, of the second P-type semiconductor layer 52. The semiconductor film layer 60 is formed in-situ process to completely cover the surface of the of the second P-type semiconductor layer 52.

Optionally, in a direction perpendicular to a plane where the substrate 10 is located, a thickness of the second P-type semiconductor layer 52 is less than a thickness of the first P-type semiconductor layer 51. The effect of the second P-type semiconductor layer 52 may be to reduce the electron concentration under the channel rather than to implement the normally-off state.

Optionally, a concentration of a P-type doping in the second P-type semiconductor layer 52 is less than a concentration of a P-type doping in the first P-type semiconductor layer 51. The effect of the second P-type semiconductor layer 52 may be to reduce the electron concentration under the channel rather than to implement the normally-off state.

Optionally, the second P-type semiconductor layer 52 and the first P-type semiconductor layer 51 are made of the same material and formed simultaneously, thereby simplifying the fabrication process.

In an embodiment, FIG. 6 is a schematic structural diagram of another semiconductor structure according to an embodiment of the present disclosure. As shown in FIG. 6, the source region 40b and the drain region 40c each include an N-type doped region 70, and the N-type doped region 70 extends into the channel layer 20. Specifically, for example, in the source region 40b, in the direction perpendicular to the plane where the substrate 10 is located, a thickness of the N-type doped region 70 is greater than a thickness of the barrier layer 30, the N-type doped region 70 is located between the source 42 and the channel layer 20, the N-type doped region 70 is in ohmic contact with the source 42, and the ohmic contact resistance between the source 42 and the channel is reduced, thereby improving the electrical performance of the semiconductor structure. The N-type doped region of the drain region has the same effect, and details are not described herein again.

Optionally, the N-type doped region 70 is heavily N-type doped, with a doping concentration greater than 1×10¹⁸/cm³.

Optionally, the N-type doped region 70 includes a superlattice structure, the superlattice may further reduce the resistance and increase the concentration of the 2DEG at the channel by the polarization effect, thereby increasing the mobility of the 2DEG.

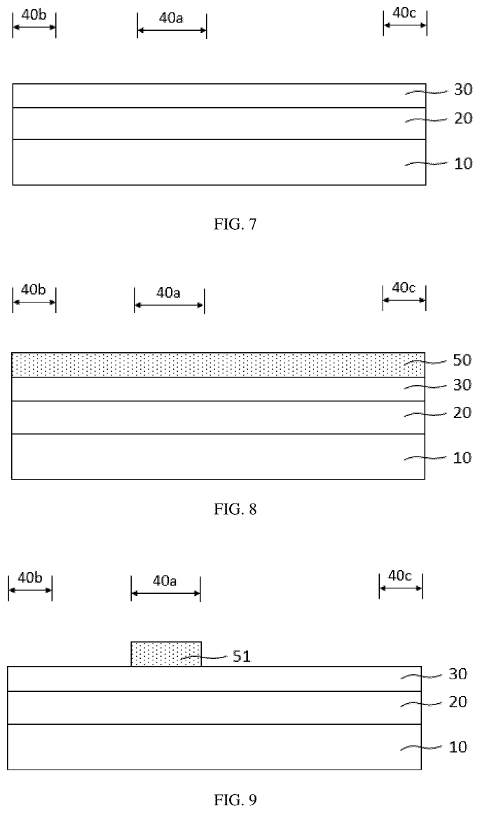

In an embodiment, the present disclosure provides a fabricating method of a semiconductor structure, FIG. 7 to FIG. 10 are schematic structural diagrams of intermediate structures for fabricating a semiconductor structure according to an embodiment of the present disclosure. The fabricating method includes the following steps.

Step S1, as shown in FIG. 7 and FIG. 14, sequentially epitaxially fabricating a channel layer 20 and a barrier layer 30 on a substrate 10, where the channel layer 20 and the barrier layer 30 include a gate region 40a, a source region 40b located at a side of the gate region 40a and a drain region 40c located at another side of the gate region 40a.

Specifically, the substrate 10 may be sapphire, Si, Iridium, diamond or GaN.

Specifically, the channel layer 20 and the barrier layer 30 may be GaN-based semiconductor materials, a material of the channel layer 20 is GaN, and a material of the barrier layer 30 is AlGaN. The epitaxial process of the channel layer 20 and the barrier layer 30 may be made by an Atomic Layer Deposition (ALD), or a Chemical Vapor Deposition (CVD), or a Molecular Beam Epitaxy (MBE), or a Plasma Enhanced Chemical Vapor Deposition (PECVD), or a Low Pressure Chemical Vapor Deposition (LPCVD), or a Physical Vapor Deposition (PVD), or a Metal Organic Source Molecular Beam Epitaxy (MOMBE), a Metal-Organic Chemical Vapor Deposition (MOCVD), or a combination thereof.

Step S2, as shown in FIG. 9 and FIG. 14, epitaxially fabricating a first P-type semiconductor layer 51 in the gate region 40a at a side, away from the substrate 10, of the barrier layer 30. Specifically, as shown in FIG. 8, the P-type semiconductor layer 50 is fabricated on a full-surface of the barrier layer 30, and the full layer is activated. Optionally, the P-type semiconductor material layer 50 other than the gate region 40a is removed by etching to obtain the first P-type semiconductor layer 51 as shown in FIG. 9. Optionally, after fabricating the P-type semiconductor layer 50 on the full-surface, only the P-type semiconductor material layer 50 (not shown) of the gate region 40a is activated, and the non-activated P-type semiconductor material layer 50 is removed by etching.

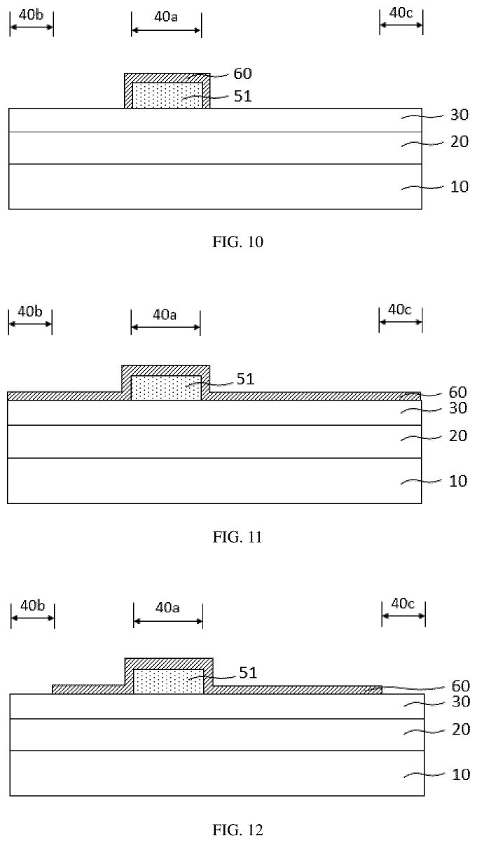

Step S3, as shown in FIG. 10 and FIG. 14, epitaxially fabricating a semiconductor film layer 60 on the first P-type semiconductor layer 51, where the semiconductor film layer 60 covers a sidewall of the first P-type semiconductor layer 51 and an upper surface, away from the substrate 10, of the first P-type semiconductor layer 51. Specifically, the semiconductor film layer 60 is epitaxially fabricated on the first P-type semiconductor layer 51, so that the defects or interface states of the surface of the first P-type semiconductor layer 51 caused by other ex-situ processes is avoided. This reduces the defect energy levels or interface states between the first P-type semiconductor layer and the semiconductor film layer, reduces the capture of electrons in the defects or interface states, and improves the current collapse, thereby improving reliability of the device.

Optionally, FIG. 11 and FIG. 12 are schematic structural diagrams of intermediate structures for fabricating another semiconductor structure according to an embodiment of the present disclosure. as shown in FIG. 11 and FIG. 12, in the Step S3, the epitaxially fabricating the semiconductor film layer 60 on the first P-type semiconductor layer 51. The fabricating method includes: as shown in FIG. 11, epitaxially fabricating the semiconductor film layer 60 on a full-surface at a side, away from the substrate 10, of the first P-type semiconductor layer 51 and at a side, away from the substrate 10, of the barrier layer 30; as shown in FIG. 12, and then etching the semiconductor film layer 60 of the source region 40b and the semiconductor film layer 60 of the gate region 40a, so that the semiconductor film layer 60 covers a region between the source region 40b and the gate region 40a and a region between the drain region 40c and the gate region 40a. In this way, the power characteristic deterioration of the device caused by over-etching the barrier layer 30 may be avoided.

Optionally, as shown in FIG. 11, the semiconductor film layer 60 is conformally fabricated at a side, away from the substrate 10, of the first P-type semiconductor layer 51 and the barrier layer 30.

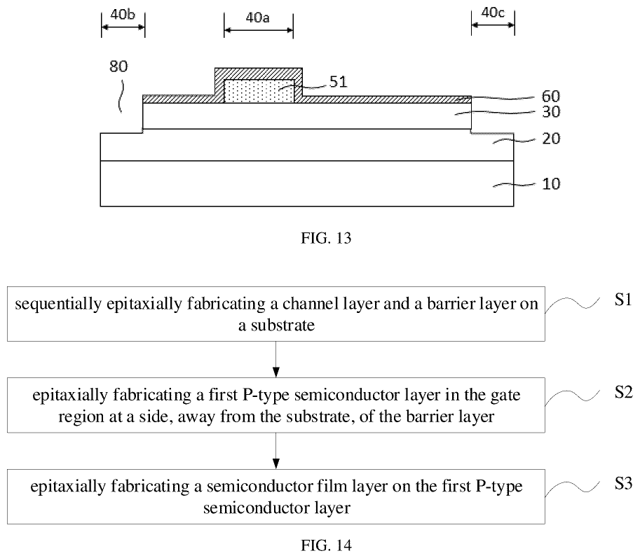

Optionally, FIG. 13 is a schematic structural diagram of an intermediate structure for fabricating another semiconductor structure according to an embodiment of the present disclosure. As shown in FIG. 13, after the semiconductor film layer 60 is fabricated epitaxially, the fabricating method further includes: etching the source region 40b and the drain region 40c to form grooves 80, respectively, where the grooves 80 extends into the channel layer, and fabricating an N-type doped region 70 by secondary epitaxially in the grooves 80. Optionally, before etching, a mask layer with an opening is first fabricated, and then the semiconductor film layer 60, the barrier layer 30 and a portion of the channel layer 20 are etched in the opening.

Optionally, in the embodiment shown in FIG. 10, the semiconductor film layer 60 is etched preferentially, then the mask layer with the opening is fabricated, and then the barrier layer 30 and the portion of the channel layer 20 (not shown) are etched in the opening.

Embodiments of the present disclosure provide a semiconductor structure and a fabricating method thereof, the semiconductor structure includes: a substrate, a channel layer and a barrier layer stacked sequentially, where the channel layer and the barrier layer include a gate region, a source region located at a side of the gate region and a drain region located at another side of the gate region; a first P-type semiconductor layer located in the gate region and at a side, away from the substrate, of the barrier layer, and the first P-type semiconductor layer is configured to implement an enhanced device; and a semiconductor film layer, where the semiconductor film layer covers a sidewall of the first P-type semiconductor layer and an upper surface, away from the substrate, of the first P-type semiconductor layer. This reduces the defects and interface states introduced on the top surface of the P-type semiconductor and the sidewall of the P-type semiconductor during the etching process, reduces the capture of electrons in the defects or interface states are reduced, and improves the current collapse, thereby improving the reliability of the device.

It should be understood that the terms “include” and variations thereof used in the present disclosure are open ended, that is, “including but not limited to”. The term “an embodiment” means “at least one embodiment”. In this specification, specific features, structures, materials, or characteristics described may be combined in any suitable manner in any one or more embodiments or examples. In addition, in the case of no contradiction, a person skilled in the art may combine and bond different embodiments or examples and features from different embodiments or examples described in the present disclosure.

What is claimed is:

1. A semiconductor structure, comprising:
a substrate, a channel layer and a barrier layer stacked sequentially, wherein the channel layer and the barrier layer comprise a gate region, a source region located at a side of the gate region and a drain region located at another side of the gate region;
a first P-type semiconductor layer located in the gate region and at a side, away from the substrate, of the barrier layer; and
a semiconductor film layer, wherein the semiconductor film layer covers a sidewall of the first P-type semiconductor layer and an upper surface, away from the substrate, of the first P-type semiconductor layer.

2. The semiconductor structure according to claim 1, wherein the semiconductor film layer covers a region between the source region and the gate region and a region between the drain region and the gate region.

3. The semiconductor structure according to claim 1, wherein a band gap of the semiconductor film layer is greater than a band gap of the first P-type semiconductor layer.

4. The semiconductor structure according to claim 1, wherein the semiconductor film layer comprises an Al element, and a content of the Al element in the semiconductor film layer is greater than or equal to 35%.

5. The semiconductor structure according to claim 4, wherein a material of the semiconductor film layer is AlGaN or AlN.

6. The semiconductor structure according to claim 1, wherein the semiconductor film layer comprises an N-type doping element.

7. The semiconductor structure according to claim 2, wherein a concentration of an N-type doping element in the semiconductor film layer between the source region and the gate region is greater than a concentration of an N-type doping element in the semiconductor film layer between the drain region and the gate region.

8. The semiconductor structure according to claim 1, wherein in a direction perpendicular to a plane where the substrate is located, a thickness of the semiconductor film layer is 2 nm-10 nm.

9. The semiconductor structure according to claim 8, wherein a thickness of the semiconductor film layer is 3 nm-5 nm.

10. The semiconductor structure according to claim 1, further comprising: a second P-type semiconductor layer located at a side, away from the substrate, of the barrier layer, and the second P-type semiconductor layer being located between the gate region and the drain region.

11. The semiconductor structure according to claim 10, wherein the semiconductor film layer covers a sidewall of the second P-type semiconductor layer and an upper surface, away from the substrate, of the second P-type semiconductor layer.

12. The semiconductor structure according to claim 10, wherein in a direction perpendicular to a plane where the substrate is located, a thickness of the second P-type semiconductor layer is less than a thickness of the first P-type semiconductor layer.

13. The semiconductor structure according to claim 10, wherein a concentration of a P-type doping in the second P-type semiconductor layer is less than a concentration of a P-type doping in the first P-type semiconductor layer.

14. The semiconductor structure according to claim 1, wherein the source region and the drain region each comprise an N-type doped region, and the N-type doped region extends into the channel layer.

15. The semiconductor structure according to claim 1, further comprising:
a gate located in the gate region and located at a side, away from the substrate, of the semiconductor film layer;
a source located in the source region and located at a side, away from the substrate, of the channel layer; and
a drain located in the drain region and located at the side, away from the substrate, of the channel layer.

16. The semiconductor structure according to claim 1, wherein in a direction from the gate region to the drain region, a thickness of a portion of the first P-type semiconductor layer gradually decreases between the gate region and the drain region.

17. A fabricating method of a semiconductor structure, comprising:
sequentially epitaxially fabricating a channel layer and a barrier layer on a substrate, wherein the channel layer and the barrier layer comprise a gate region, a source region located at a side of the gate region and a drain region located at another side of the gate region;
epitaxially fabricating a first P-type semiconductor layer in the gate region at a side, away from the substrate, of the barrier layer; and
epitaxially fabricating a semiconductor film layer on the first P-type semiconductor layer, wherein the semiconductor film layer covers a sidewall of the first P-type semiconductor layer and an upper surface, away from the substrate, of the first P-type semiconductor layer.

18. The fabricating method of the semiconductor structure according to claim 17, wherein the epitaxially fabricating a semiconductor film layer on the first P-type semiconductor layer comprises:
epitaxially fabricating the semiconductor film layer on a full-surface at a side, away from the substrate, of the first P-type semiconductor layer and at a side, away from the substrate, of the barrier layer, so that the semiconductor film layer covers a region between the source region and the gate region and a region between the drain region and the gate region.

19. The fabricating method of the semiconductor structure according to claim 18, wherein the semiconductor film layer is conformally fabricated at a side, away from the substrate, of the first P-type semiconductor layer and the barrier layer.

20. The fabricating method of the semiconductor structure according to claim 17, wherein after the semiconductor film layer is fabricated epitaxially, the fabricating method further comprises:
etching the source region and the drain region to form grooves, respectively, wherein the grooves extends into the channel layer; and
fabricating an N-type doped region by secondary epitaxy in the grooves.
